(19) United States
(12) Patent Application Publication
(10) Pub. No.: US 2004/0062016 A1
(43) Pub. Date: Apr. 1, 2004

(54) Medium having data storage and communication capabilites and method for forming same

(75) Inventors: Roger S. Kerr, Brockport, NY (US); Timothy J. Tredwell, Fairport, NY (US)

Correspondence Address: PATENT LEGAL STAFF, EASTMAN KODAK COMPANY, 343 STATE STREET, ROCHESTER, NY, 14650-2201, US

(73) Assignee: Eastman Kodak Company

(21) Appl. No.: 10/256,824

(22) Filed: Sep. 27, 2002

(51) Int. Cl. H05K 7/06

(52) U.S. Cl. 361/761; 361/762

(57) ABSTRACT

A method for forming a medium is provided. A base layer is provided. A material layer is provided with the material layer having a void. A transponder having a memory is positioned in the void. A medium is also provided. The medium has a base layer and a material layer joined to the base layer. The material layer has a void. A transponder having a memory is positioned in the void.

### CROSS REFERENCE TO RELATED APPLICATIONS

Reference is made to commonly assigned copending U.S. patent application Ser. No. ______ (Docket 84691RRS) filed herewith, entitled MEDIUM HAVING DATA STORAGE AND COMMUNICATION CAPABILITIES AND METHOD FOR FORMING SAME, by Kerr et al. and U.S. patent application Ser. No. 10/161,514, entitled VIRTUAL ANNOTATION OF A RECORDING ON AN ARCHIVAL MEDIA by Kerr et al. filed on ______.

### FIELD OF THE INVENTION

The present invention relates in general to the field of mediums and more particularly to mediums having electronic memory associated therewith.

### BACKGROUND OF THE INVENTION

Thin mediums of material such as paper, film and fabric have many useful applications. Often images and information are recorded on such mediums. Where information regarding characteristics of the medium is known in advance of the recording process, the recording process can be adjusted to improve the quality of the recording. Once a recording has been made on a medium it can be useful to associate electronic information in a memory that is associated with the medium. Such electronic information can include information that describes the chain of custody of the medium, the use of the medium, and who has accessed the medium. Radio Frequency Identification (RFID) tags typically comprise three principal elements, an antenna and transponder that cooperate to send and receive electromagnetic fields containing information and a memory that stores information. Other useful information can also be associated with the medium such as electronic information that depicts information recorded on the medium. See for example, commonly assigned U.S. pat. appl. Ser. No. 10/161,514, entitled Virtual Annotation of a Recording on an Archival Media, filed by Kerr et al. on Jun. 3, 2002.

It is known to use Radio Frequency Identification (RFID) tags to provide the electronic memory and communication capabilities that allow electronic information to be associated with a medium.

The RFID tag is adapted to exchange information with a co-designed reading/writing device. Information that is stored in an RFID tag that is joined to an item can later be used to track, identify and process the item. The RFID tag can also store other information that is to be associated with the item. A commercially available “TAG-IT INLAY”™ RFID tag available from Texas Instruments, Incorporated, Dallas, Tex., USA, can be used to provide identifying information about an item to which it is attached. This relatively thin, flexible type of RFID tag can be used in applications that previously required a label or bar code. The RFID tags of the prior art are typically used for identification purposes, such as for employee badges, inventory control, and credit card account identification. The advantage of such RFID tags is that they are small in size, easy to communicate with and unlike a bar coded item, do not require the item to be aligned to the reader or scanner.

RFID tags have been proposed for use in applications with passports and credit cards, such as is disclosed in U.S. Pat. No. 5,528,222 filed by Moskowitz et al. These devices are useful for tracking the location, characteristics and usage of documents, books and packages. For example, such tags can be used to track the location of documents and track the chain of custody of such documents within a document management system.

RFID tags are typically formed into a package such as an inlay, a plastic glass or ceramic housing. The RFID package is then joined to an item such as a document or book after the item has been fully assembled. Typically the RFID tag has an adhesive surface that is used to form a bond between the RFID tag and the item to which it is being joined. It is also known to use other ways of mechanically joining an RFID tag to an item. For example, an RFID tag can be joined to an item using a staple or other mechanical fastener.

There is room for improvement in this arrangement. For example, a poor bond or poor mechanical joint between the RFID tag and the item can result in separation of the RFID tag from the item. This can defeat the purpose of joining the RFID tag to the item. Further, joining an RFID tag to an item increases the cost of the combined RFID tag and item because the RFID tag must include the cost of both the base and the fastener and the cost of labor associated with joining the RFID tag to the item. These costs can become significant where RFID tags are to be joined to a multiplicity of individual items, for example, individual sheets of medium such as film or paper.

Additionally, such RFID tags typically take the form of a patterned antenna located on a base having a transponder unit applied to the top of the antenna. Accordingly, such RFID tags have a non-uniform cross-sectional area. The non-uniform cross-section of the tag can make the tag vulnerable to incidental damage to contact during manufacturing, printing, use, storage and distribution. Further, such RFID tags can interfere with the appearance and the use of the item.

One approach for solving these problems is to incorporate RFID tags inside an item such as an identification badge. In one example, this is done by providing a clam shell type outer casing into which the RFID and antenna electronics are deposited. An example of such an identification badge is the ProxCard II proximity access card sold by HID Corporation, Irvine, Calif., USA. Thinner cards are made by sandwiching the RFID and antenna electronics between sheets of laminate material. An example of such a badge is the ISO ThinCard sold by HID Corporation, Irvine, Calif., USA. While this method of forming a card produces a card that is thinner than the clam shell type card, the card has an uneven cross-section with increased thickness in the area of the RFID electronics.

These techniques, however, are not feasibly applied to the task of forming a thin medium such as paper, film and fabric. Such thin mediums are typically fabricated in high volumes using coating, extrusion and rolling techniques to convert pulp, gelatin or other material into thin sheets of material that are then processed into useful forms. The addition of clam shell type structures known in the art is not practically or economically feasible in this type of production. The alternative lamination approach of the prior art is also not preferred because the increased thickness and uneven cross section caused by the presence of RFID electronics and antenna sandwiched between laminations, can interfere with subsequent fabrication processes causing damage to fabrication equipment and the RFID electronics and or to the medium itself. Further this uneven cross section can interfere with imaging equipment and medium when the laminated medium having an RFID unit is passed through equipment such as a printer that uses a medium after formation. This interference can damage the RFID tag, the medium and the equipment that uses the medium. The uneven cross section also creates a less than desirable appearance for the medium and images that are subsequently recorded thereon.

Thus a need exists for a medium that has the ability to store and electronically exchange data with the medium being compatible with conventional web fabrication processes and post fabrication uses of the medium.

### SUMMARY OF THE INVENTION

In one aspect, the present invention comprises a method for forming a medium. A base layer is provided. A material layer is provided with the material layer having a void. A transponder having a memory is positioned in the void.

In another aspect what is provided is a method for forming a medium. An antenna layer is on a base layer. The antenna layer has an antenna formed therein. A transponder having a memory and adapted to cooperate with the antenna is provided. A material layer is joined to the antenna layer. The material layer has a thickness that is at least equal to the thickness of the transponder and has at least one void sized to receive the transponder is joined to the antenna layer. The transponder is positioned in the void to cooperate with the antenna.

In another aspect, a medium is provided. The medium has a base layer. A material layer is joined to the base layer with said material layer having a void. At least one transponder having a memory is in the void.

In another aspect what is provided is a medium having base layer. An antenna layer is on the base layer. The antenna layer has an antenna formed therein. A transponder having a memory and adapted to cooperate with the antenna is provided. A material layer is joined to the antenna layer. The material layer has a thickness that is at least equal to the thickness of the transponder and has at least one void sized to receive the transponder. The transponder is positioned in the void to cooperate with the antenna.

### BRIEF DESCRIPTION OF THE DRAWINGS

A more complete understanding of the invention and its advantages will become apparent from the detailed description taken in conjunction with the accompanying drawings, wherein examples of the invention are shown, and identical reference numbers have been used, where possible, to designate identical elements that are common to the figures referenced below:

FIG. 1 shows a cross section view of one embodiment of the medium of the present invention;

FIG. 2 shows an exploded cross-section view of the embodiment of FIG. 1;

FIG. 3 shows a top perspective view of a base layer having an antenna layer formed thereon;

FIG. 4 illustrates one embodiment of the method for joining the material layer to a base layer having an antenna layer formed thereon;

FIG. 5 shows a top perspective view of a base layer having an antenna layer and a material layer formed thereon;

FIG. 6 shows the medium of FIG. 5 with transponders formed thereon;

FIGS. 7-9 show various embodiments of mediums having voids with a transponder installed thereon;

FIGS. 10-11 show cross sectional views of a medium with voids having walls with shaped features to help receive and hold a transponder in a void;

FIG. 12 is a cross section view of an embodiment having an overcoat layer.

FIG. 13 is a cross-section and exploded view of the embodiment of FIG. 12;

FIG. 14 is a cross-section view of an embodiment of the present invention having additional antenna, material and overcoat layers;

FIG. 15 is a cross-section view of an embodiment of the present invention having an adhesive layer.

### DETAILED DESCRIPTION OF THE INVENTION

The present invention will be directed in particular to elements forming part of, or in cooperation more directly with the apparatus in accordance with the present invention. It is to be understood that elements not specifically shown or described may take various forms well known to those skilled in the art.

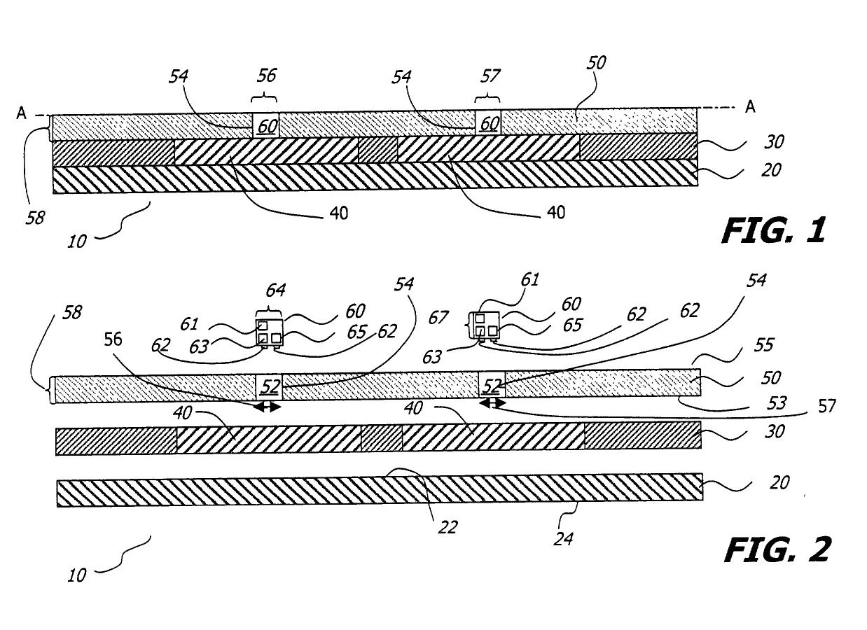

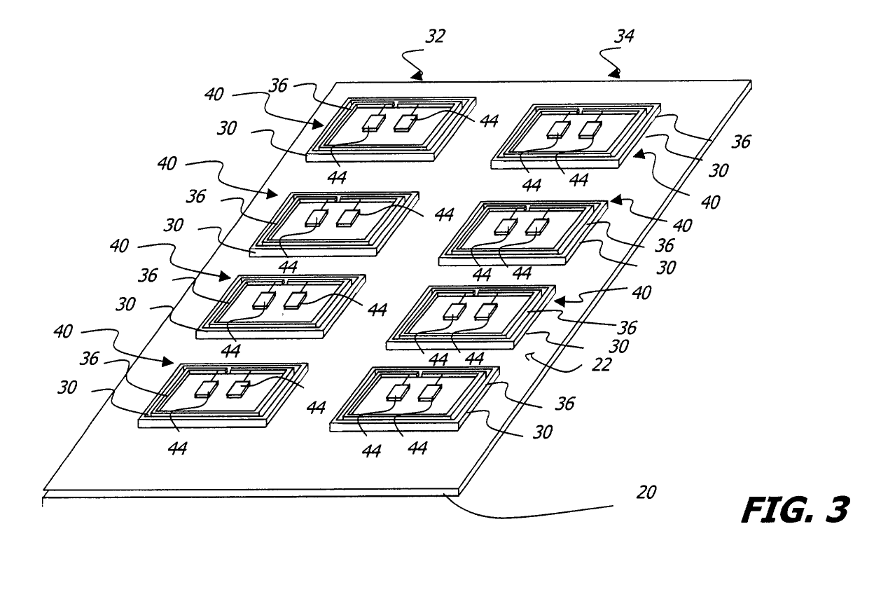

An embodiment of the present invention will now be shown and described with reference to FIGS. 1-3. FIGS. 1 and 2 respectively show a cross-section view of one embodiment of the medium 10 of the present invention and an exploded cross-section view of the medium 10. FIG. 3 shows a top right perspective view of a base layer having an antenna layer formed thereon.

As is shown in FIGS. 1 and 2 medium 10 has a base layer 20 having a top surface 22 and a bottom surface 24. Base layer 20 can be formed from a material such as a paper, plastic, metal, fabric, or other convenient substrate. In certain embodiments, the material used in base layer 20 is selected to receive image forming materials such as inks, dyes, toners, and colorants. This permits images to be formed for example on bottom surface 24 using ink jet printing, thermal printing, contact press printing and other techniques. Alternatively, base layer 20 can also selected to form images when exposed to energy such thermal, electrical, optical, electromagnetic or other forms. In a further alternative a top or bottom surface of can be adapted by chemical or other treatments or coatings to receive images. In the embodiment shown, base layer 20 has a thickness of approximately 100 microns however, the thickness of base layer 20 is not critical.

In the embodiment that is shown in FIGS. 1-3, an antenna layer 30 is formed on top surface 22 of base layer 20. Antenna layer 30 comprises a material that is capable of being used to form an antenna. Examples of such materials include metals such as copper, aluminum and other materials having electrically conductive properties. Antenna layer 30 has patterned antennas 40 formed therein. FIG. 3 shows a top view of a base layer 20 having patterned antennas 40 applied thereon. Antennas 40 are shown arranged in a first row of antennas 32 and a second row of antennas 34. However other arrangements and distributions of antennas 40 can be used. Each one of antennas 40 has an antenna section 42 and mating surfaces 44. As is shown in FIG. 3, rows of antennas 32 and 34 extend longitudinally along top surface 22 of base layer 20. However, where medium 10 has two or more antennas 40, such antennas can be arranged on antenna layer 30 in any useful pattern.

As is also shown in FIG. 3 each of antennas 40 is formed from patterns of antenna layer 30 and spaces 46 in antenna layer 30. The arrangement of spaces 46 that form the pattern of material comprising antennas 40 can be formed by applying antenna layer 30 to top surface 22 in a patterned fashion. This can be done for example by using printing, lamination, thermal transfer, or laser thermal transfer techniques to selectively transfer antenna layer 30 to top surface 22. Alternatively, antenna layer 30 can be applied to top surface 22 to form a uniform layer, and portions of antenna layer 30 can be selectively removed to form spaces 36. This selective removal can be done by etching or oblation processes that chemically, optically, thermally remove material from antenna layer 30 to form spaces 36 that define patterned antennas 40. Mechanical processes can also be used to remove material from antenna layer 30 to form patterned antennas 40.

A material layer 50 is provided. Material layer 50 can comprise a material including paper, film, polymer or other materials. In one embodiment, material layer 50 is formed from BUTVAR polyvinyl butgral (PVB) resin sold commercially by Solutial, St. Louis, Mo., USA. In the embodiment shown in FIGS. 1 and 2 material layer 50 is formed from a material that receive image forming substances such as inks, dyes, pigments, colorants, used in the formation of images. In other embodiments, material layer 50 can be formed from a material that can be thermally, chemically or optically modified to form an image. In still other embodiments, material layer 50 can be chemically treated to adapt material layer 50 to receive images or to facilitate modification of the material layer 50 to permit formation of images thereon.

Material layer 50 is fabricated separately from base 20 and/or antenna layer 30. During formation of the material layer 50, voids 52 are formed in material layer 52. These voids 52 are shown passing from a top surface 51 of material layer 50, through the material layer to a bottom surface 53. However, this is not necessary as voids 52 can comprise any form of void within material layer 52 that can receive a transponder 60 and/or an antenna.

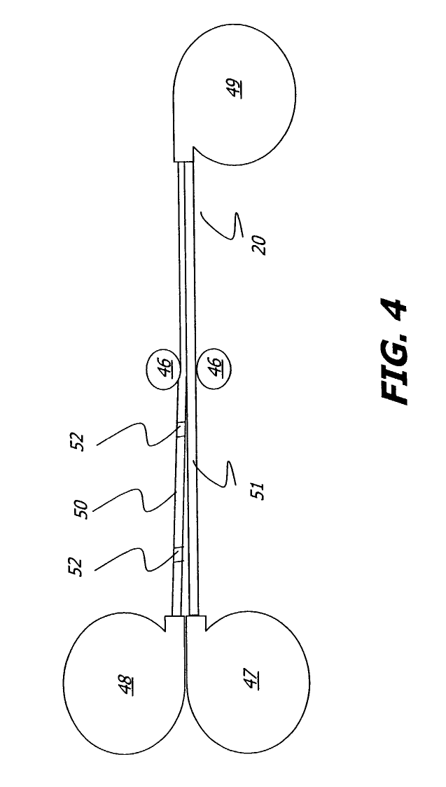

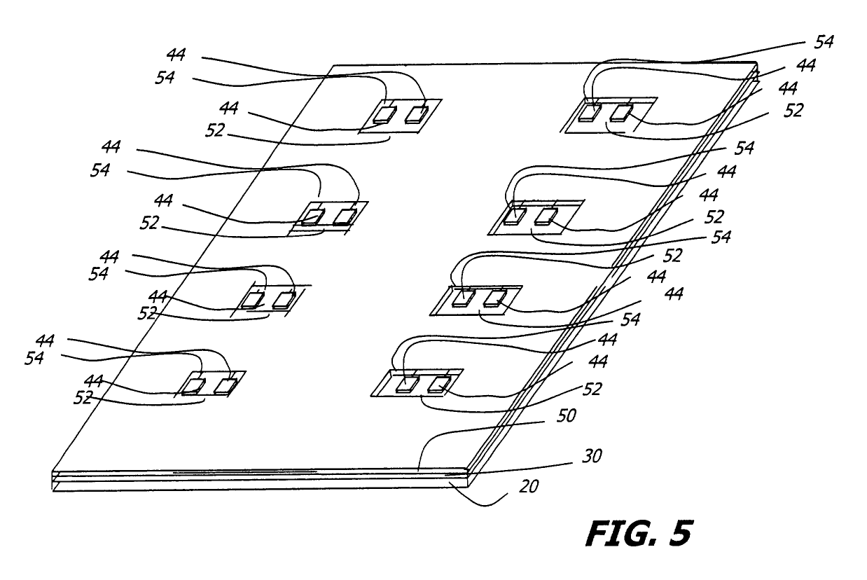

FIG. 4 shows one embodiment of a material layer 50 that is formed in rolls and applied to a web 51 having an antenna layer 30 thereon. Various techniques can be used to join material layer 50 to web 51. For example material layer 50 can be joined to base layer 20 and/or antenna layer 30 using adhesives, pressure mounting or other techniques known in the art for joining a first layer of a material to a second layer. FIG. 5 illustrates one example of this. As is shown in FIG. 4, web 51 of a base layer 20 having an antenna layer 30 is supplied by a web supply reel 47 and a material layer 50 having voids 52 is supplied by a material reel 48 by a pair of rollers 46 that press the material layer 50 onto web 51. Either of web 51 or material layer 50 can be heated to facilitate bonding. This can be done for example by heating rollers 46. The combined medium 20 is stored on a take up reel 49.

FIG. 5 shows a perspective view of a medium 20 formed by joining the material layer 50 to web 51. In the embodiment shown in FIGS. 1-6, transponders 60 have antenna engagement surfaces 62 defined to engage co-designed mating surfaces 44 formed on antenna layer 30 to provide an electrical connection. Using this electrical connection, power supply circuit 65 can receive electromagnetic signals that it converts into power that operates transponder 60. This electrical connection can also be used to receive radio frequency signals having data. Transponders 60 each include a memory 61. When transponder 60 is operated, radio frequency communication circuit 63 uses the electrical connection between mating surfaces 44 and antenna engagement surfaces 62 to transmit radio frequency signals that contain data from memory 61. Radio frequency circuit 63 can also be used to receive radio frequency signals containing data and to store the data in memory 63.

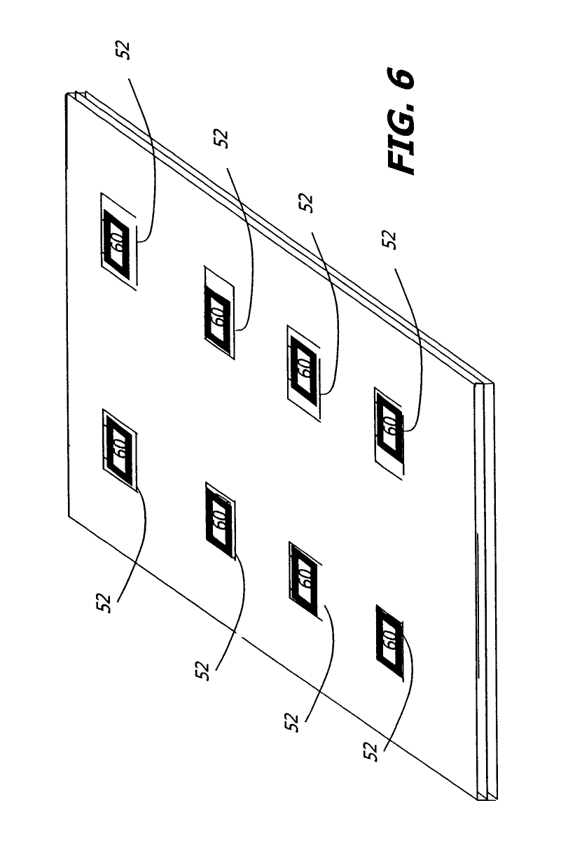

FIG. 6 shows the medium 20 of FIG. 5 with transponders 60 joined thereto. Transponders 60 are positioned in voids 52. In the embodiment shown, voids 52 have openings at both of an inner surface 53 and an outer surface 55 of material layer 50. In this embodiment transponders 60 can be inserted into voids 52 after formation of material layer 50. Voids 52 are arranged so that insertion of transponders 60 into voids 52 brings antenna engagement surfaces 62 into contact with co-designed mating surfaces 44 formed on antenna layer 30 to provide an electrical connection between engagement surfaces 62 and mating surfaces 44. In one embodiment, material layer 50 can be formed with transponders 60 inserted into voids 52 prior to joining material layer 50 to web 51. In still another embodiment, transponders 60 can be joined to web 51 prior to joining material layer 50 to web 51.

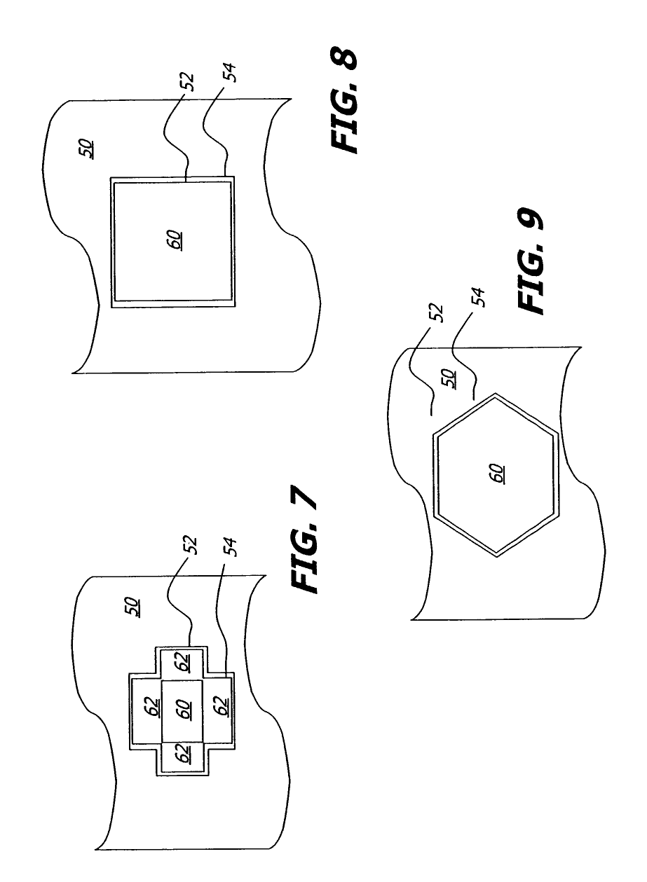

In the embodiment shown, voids 52 are sized to receive transponders 60 having a width dimension 56 and 57 that is at least equal to a width dimension 64 of transponders 60. Alternatively, as will be described in greater detail below, where material layer 50 is formed from a material having a degree of elasticity, the width dimension 56 of voids 52 can be undersized with respect to a width dimension 64 of transponders 60. Where voids 52 are undersized, insertion of transponders 60 into voids 52 causes deformation of material layer 50. Material layer 50 resists this deformation and applies a force against transponders 60. This force tends to hold transponders 60 within voids 52 and can be used to hold transponders 60 so that engagement surfaces 62 remain in contact with mating surfaces 44 of antennas 40 and do not slide along void 52 in a manner that would cause separation of engagement surfaces 60 from mating surfaces 44 Voids 52 have a void wall 54. Void wall 54 can be shaped to align or otherwise position transponder 60 so that the antenna engagement surfaces 62 can engage mating surfaces 44 to provide an electrical connection between transponders 60 and an antenna such as antenna 32. The shape of void wall 54 can be matched to a particular footprint of a particular transponder 60. The shape of the void wall 54 can be a simple shape such as a square circle or a more complex form such as a cross, rectangle or other useful form, some examples of which are shown in FIGS. 7, 8 and 9.

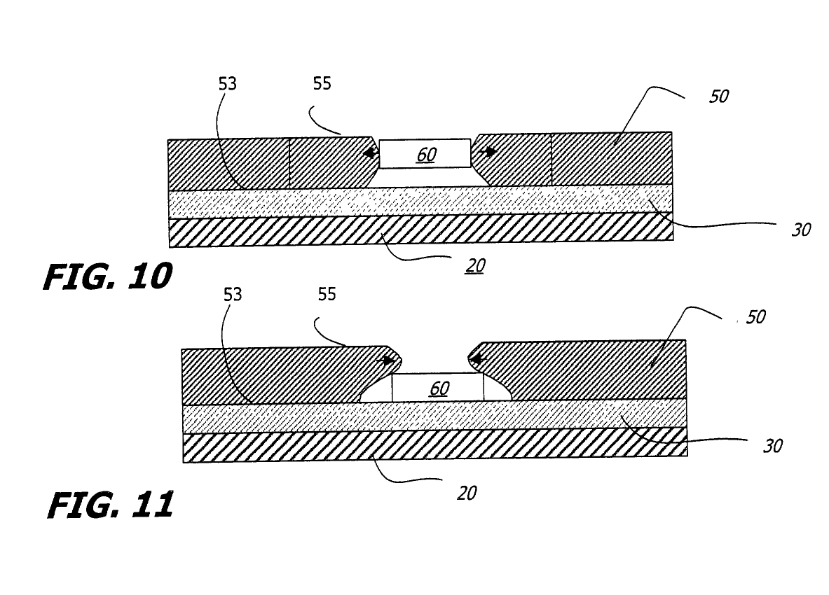

FIGS. 10 and 11 show cross sectional views of a void 52 having void walls 54 that are shaped with features to help receive and to hold transponder 60 in void 52. As is shown, in FIGS. 10 and 11 void walls 54 are narrower near outer surface 55 and wider near inner surface 53. In this embodiment, material layer 50 is made from a material that permits some degree of elastic deformation. Accordingly, as shown in FIG. 10 when a transponder 60 is pressed into the portion of void walls 54 that is near outer surface 55, material layer 50 deforms to accept transponder 60 into the portion of void walls 54 that is near inner surface 55. The portion of void walls 54 near to the top surface of material layer 52 then elastically expands as shown in FIG. 11 to capture transponder 30 in material layer 52 in an area proximate to antenna layer 30.

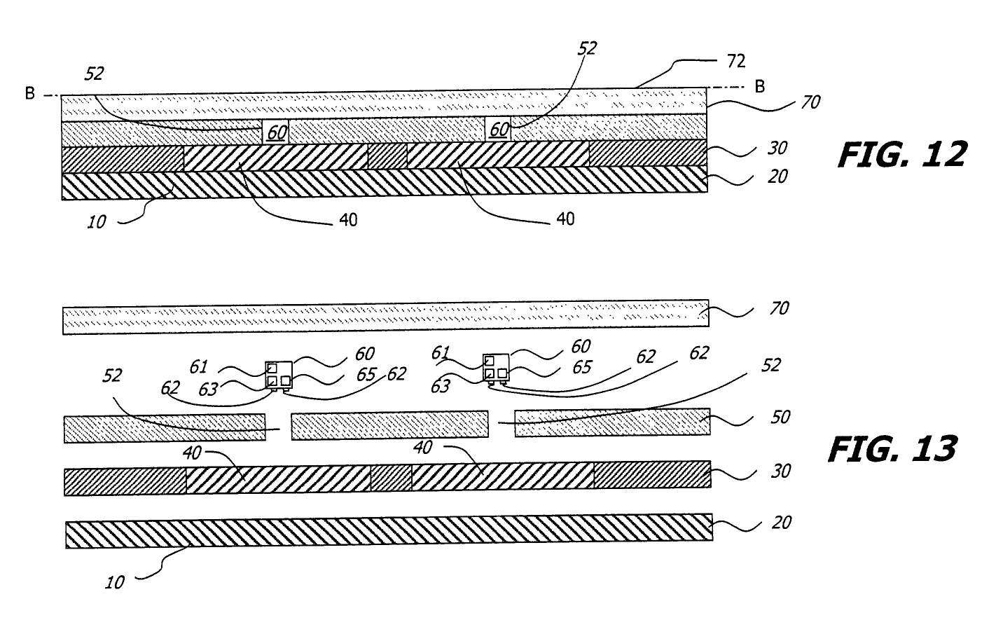

As is shown in FIGS. 12 and 13, in another embodiment, an overcoat layer 70 can be applied to material layer 50. In this embodiment, overcoat layer 70 secures transponders 60 in perforations 52 respectively. Further, overcoat layer 70 seals and fills material layer 50 so that no portion of antenna layer 30 remains exposed after overcoat layer 70 has been applied. Overcoat layer 70 can be applied to fill portions of slots 52 and 54 that are not occupied by transponders 60. This helps to secure transponder 60 and prevent movement of transponder 60 along slots 54 and 52. Overcoat layer 70 can be adapted to receive image-forming materials. In the embodiment that is shown in FIGS. 12 and 13, overcoat layer 70 is applied to form a top surface B-B that does not have protrusions caused by transponders 60. Alternatively, overcoat layer 70 can also be adapted to cushion and protect transponders 60 from thermal or mechanical damage during handling or manipulation of medium 20.

Where an overcoat layer 70 is used, it is not essential that material layer 50 has a thickness that is at least as great as the thickness of transponders 60. This is because a common plane e.g. B-B can be formed by a top surface 72 of overcoat layer 70 wherein overcoat layer 70 is applied to a thickness that, in combination with material layer 50 has a thickness that is at least as thick as the thickness of transponders 60.

Where material layer 50 is adapted to receive image forming materials and such image forming materials can be applied to form images on material layer 50 before overcoat layer 70 is formed. In one such embodiment, overcoat layer 70 can comprise a transparent material that block the flow of ultraviolet or other forms of radiation or that provides protection against mechanical, thermal, chemical or other factors that may damage the appearance of the images formed on material layer 50.

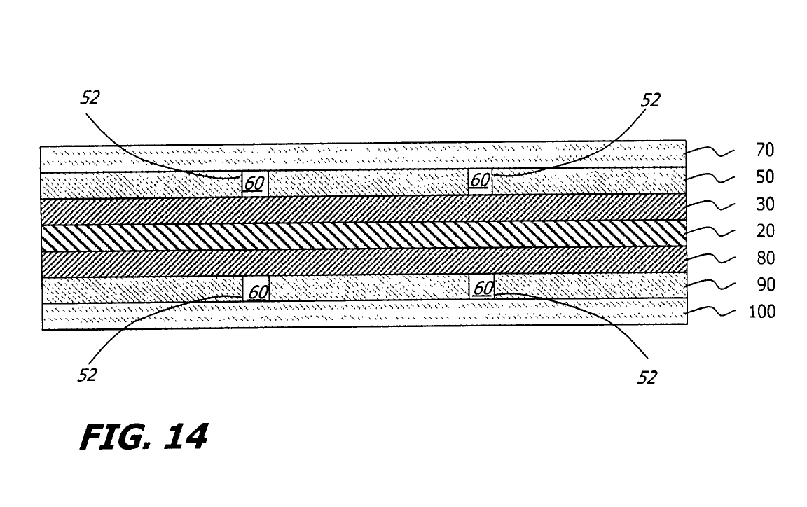

As is shown in FIG. 14, an additional antenna layer 80 can be formed on bottom surface 24 of base layer 20. Additional antenna layer 80 can be formed in the manner described above with respect to forming antenna layer 30. Similarly, an additional material layer 90 can be applied to additional antenna layer 80 with voids 92 formed therein. Voids 92 are adapted to receive transponders 60 and are otherwise similar to voids 52 as described above. As is also shown in FIG. 14 an additional overcoat layer 110 can optionally be applied to additional material layer 90.

In this embodiment, medium 10 is free of protrusions, thus medium 10 can be further processed as necessary using conventional web forming techniques such as winding, rolling, extruding and printing can be applied to medium 10 after transponder 60 has been positioned in the material layer of medium 10. For example, a medium 10 having a transponders 60 attached thereto can be slit and wound onto rolls with each roll having at least one transponder 60. Medium 10 can also be slit and chopped into sheet form with each sheet having a transponder 60 associated therewith.

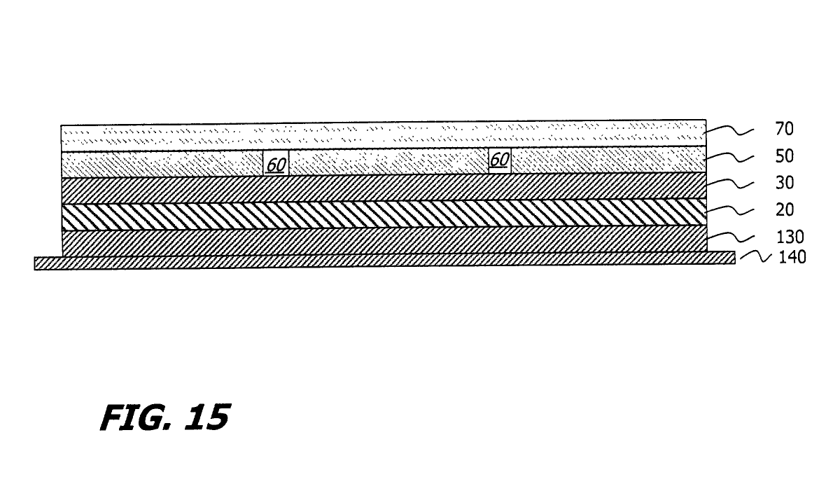

As is shown in FIG. 15, an adhesive layer 110 can be applied to base layer 120 of medium 10 to permit medium 10 to be easily applied to a tangible thing such as a bottle. An advantage of such a medium is that a label can be provided that does not have a protrusion that might interfere with or be easily damaged by use and handling of the tangible thing to which the medium is attached. To facilitate handling of this adhesive embodiment of medium 10, a removable layer 120 can be applied to adhesive layer 110.

As described herein, any base layer 20, antenna layer 30, material layer 50, and over coat layer 70 can comprise multiple layers.

Further, in any embodiment described transponder 60 can be formed in whole or in part by depositing circuit forming material on medium 20. For example, transponder 30 can be formed on base layer 20, antenna layer 30, or in antenna layer 30 using lithographic, ink jet and other technologies that permit electronic circuits to be formed on a substrate. Transponder 60 can also be incorporated into voids 52 in material layer 50 before material layer 50 is joined to web 51.

The invention has been described in detail with particular reference to certain preferred embodiments thereof, but it will be understood that variations and modifications can be effected within the spirit and scope of the invention.

### Parts List

| | |
|---|---|
| 10 | medium |
| 20 | base layer |
| 22 | top surface |
| 24 | bottom surface |
| 30 | antenna layer |
| 32 | row of antennas |
| 34 | row of antennas |
| 36 | spaces |
| 40 | antennas |
| 42 | antenna section |
| 44 | mating surface |
| 46 | roller |
| 47 | web supply reel |
| 48 | material supply reel |
| 49 | take up reel |
| 50 | material layer |
| 51 | web |
| 52 | void |
| 53 | inner surface |
| 55 | outer surface |
| 56 | width dimension |
| 57 | width dimension |
| 59 | top surface |
| 60 | transponders |
| 62 | engagement surface |
| 63 | memory |
| 64 | width dimension of transponder |
| 65 | radio frequency communication |
| 66 | Top surface of transponder |
| 70 | overcoat layer |
| 80 | additional antenna layer |
| 90 | additional material layer |
| 92 | voids |
| 100 | additional overcoat layer |
| 110 | adhesive layer |
| 120 | removable layer |

What is claimed is:

1. A method for forming a medium comprising the steps of:
providing a base layer;
joining a material layer on the base layer with said material layer having a void; and,
positioning a transponder having a memory in the void.

2. The method of claim 1, further comprising the step of forming an antenna layer having an antenna on the base layer wherein the transponder is adapted to cooperate with the antenna when the transponder is positioned in the void.

3. The method of claim 1 wherein said transponder has a thickness and wherein the step of joining a material layer having a void comprises joining a material layer having a thickness that is at least equal to the thickness of the transponder.

4. The method of claim 1 wherein the material layer has a void with a width dimension that is smaller in size than a width dimension of the transponder and the step of positioning the transponder in the void comprises elastically deforming the material layer proximate to the void to receive the transponder.

5. The method of claim 1 further comprising the step of providing an overcoat layer on the material layer with the overcoat layer adapted to permit the formation of an image thereon.

6. The method of claim 1, further comprising the step of providing an overcoat layer on the material layer, void and transponder.

7. The method of claim 1, further comprising the step of providing an overcoat layer on the material layer, void and transponder to form a generally uniform outer surface.

8. The method of claim 1, wherein said material layer comprises material upon which an image can be formed.

9. The method of claim 2, wherein the step of forming the antenna layer comprises printing an antenna material onto the base in a pattern to form said antenna.

10. The method of claim 2, wherein the step of forming the antenna layer comprises the steps of providing a layer of antenna material and etching at least one antenna pattern in said antenna layer.

11. The method of claim 2, further comprising the step of providing an overcoat layer on the material layer, the transponder and the antenna layer said overcoat layer adapted to permit the formation of an image thereon.

12. The method of claim 2 further comprising the step of providing an overcoat layer on the material layer, transponder and antenna to form a generally uniform outer surface.

13. The method of claim 1 wherein the step of providing a base layer comprises providing a base layer having a bottom surface adapted to receive an image.

14. The method of claim 1 wherein the step of providing a base layer comprises providing a base layer having a bottom surface and applying a coating of material upon which an image can be formed.

15. The method of claim 1, further comprising the step of allying an overcoat layer adapted to provide protection against at least one of chemical, radiation, mechanical, electrical or optical damage.

16. The method of claim 1, further comprising the step of forming the medium into a roll having at least one roll transponder.

17. The method of claim 1, further comprising the steps of forming the medium into at least one sheet with each sheet having at least one transponder.

18. The method of claim 1, further comprising the step of recording data in the memory.

19. The method of claim 1 wherein the step of positioning a transponder in the void comprises forming a transponder in the void.

20. The method of claim 2 wherein the steps of positioning a transponder in the void comprises forming a transponder on the antenna layer in the void.

21. The method of claim 1 wherein the step of positioning a transponder in the void comprises positioning a transponder having an antenna in the void.

22. A method for forming a medium, the method comprising the steps of:
forming an antenna layer having an antenna on a base layer;
providing a transponder having a memory and adapted to cooperate with the antenna with the transponder having a thickness;
joining a material layer to the antenna layer, the material layer having a thickness that is at least equal to the thickness of the transponder and having a void sized to receive the transponder; and,
positioning the transponder in the void so that the transponder can cooperate with the antenna formed on the antenna.

23. The method of claim 22 wherein the transponder has a thickness within a predefined range and wherein the step of joining a material layer to the antenna comprises joining a material layer having a thickness that is at least equal to the thickness of the at least one transponder.

24. The method of claim 22 wherein the material layer has a width dimension that is smaller in size than a width dimension of the at least one transponder and the step of positioning the transponder in the void comprises elastically deforming the material layer proximate to the void to receive the transponder.

25. The method of claim 22 further comprising the step of providing an overcoat layer with the overcoat layer formed from a material upon which an image can be formed.

26. The method of claim 22, further comprising the step of providing an overcoat layer on each material layer, void and transponder.

27. The method of claim 22, further comprising the step of providing an overcoat layer on said material layer, void and transponder to form a generally planar outer surface.

28. The method of claim 22, wherein said material layer is formed from a material upon which an image can be formed.

29. The method of claim 22 wherein said material layer is adapted to permit the formation of an image thereon.

30. The method of claim 22 wherein the base layer has two sides and wherein the step of forming an antenna layer comprises forming an antenna layer having an antenna on each side.

31. The method of claim 30 wherein said antenna layers are printed onto both sides of the base layer by a thermal transfer printer.

32. The method of claim 30, wherein the step of forming said second antenna layer comprises the steps of providing a layer of antenna material on the opposite side of the base layer and etching at least one antenna pattern into each side.

33. The method of claim 30, wherein the step of joining a material layer to the antenna layer comprises joining a material layer to each antenna layer.

34. The method of claim 33, further comprising the step of providing an overcoat layer on each material layer, each overcoat layer adapted to permit the formation of an image thereon.

35. The method of claim 22, further comprising the step of forming the medium into rolls each having at least one transponder.

36. The method of claim 22, further comprising the step of recording data in the memory.

37. The method of claim 22 further comprising the step of forming the recording medium into at least one sheet with each sheet having at least one transponder.

38. A medium comprising:
a base layer;
a material layer joined to the base layer with said material layer having avoid; and, at least one transponder having a memory in the void.

39. The medium of claim 38 further comprising the step of providing an overcoat layer on the material layer said overcoat layer being formed from a material that permits the formation of an image thereon.

40. The medium of claim 38 further comprising an antenna layer having an antenna.

41. The medium of claim 40 wherein the antenna layer comprises a patterned antenna material.

42. The medium of claim 40, wherein the antenna layer comprises a layer of antenna material having an etched antenna pattern.

43. The medium of claim 38 further comprising an overcoat layer adapted to provide protection against at least one of chemical radiation, mechanical, electrical or thermal damage.

44. The medium of claim 38 further comprising an overcoat layer on the base layer opposite the antenna layer said overcoat layer adapted to permit the formation of an image thereon.

45. The medium of claim 38 further comprising an overcoat layer on the material layer said overcoat layer adapted to permit the formation of an image thereon.

46. The medium of claim 38 further comprising an adhesive layer.

47. The medium of claim 38 wherein said base layer is formed from a material that permits formation of an image thereon.

48. The medium of claim 38 wherein said transponder has a thickness within a predefined range and said material layer has a thickness at least equal to the thickness of said transponder.

49. The medium of claim 38 wherein said transponder has a width dimension said material layer comprises an elastically deformable material and said void has a width dimension smaller than the width dimension of said transponder.

50. The medium of claim 38 further comprising an overcoat layer adapted to provide protection against at least one of chemical, radiation, mechanical, electrical or thermal damage.

51. The medium of claim 45 wherein the base layer has a bottom surface coated with a material upon which an image can be formed.

52. A medium comprising:
an antenna on a side of a base layer,
a transponder with having a memory and an interface patterned to cooperate with at least one antenna the transponder having a thickness; and
a material layer joined to the antenna layer, the material layer having a void sized to receive said transponder;
wherein said transponder is positioned in the void to cooperate with the antenna.

53. The medium of claim 52 further comprising an overcoat layer on the material layer said overcoat layer being formed from a material that permits an image to be formed thereon.

54. The medium of claim 52 wherein said material layer formed from a material that permits the formation of an image thereon.

55. The medium of claim 52 wherein the base layer is formed from a material that permits an image to be formed thereon.

56. The medium of claim 52 wherein said antenna layer is printed onto the base.

57. The medium of claim 52 wherein said overcoat layer is adapted to protect the medium from at least one of thermal, radiation, chemical, mechanical or damage.

58. The medium of claim 52 further comprising a second material layer having a second void joined to a second side of the base and a second transponder located in the second void.

59. The medium of claim 58 further comprising a second antenna layer between the second material layer and the base said second material layer comprising an antenna.

60. The medium of claim 52 wherein said transponder is formed on the medium.

61. The medium of claim 52 wherein said transponder is formed in the void.
